(19) United States
(12) Patent Application Publication
(10) Pub. No.: US 2017/0124931 A1
(43) Pub. Date: May 4, 2017

(54) METHOD AND SYSTEM FOR PERFORMING PANEL VIBRATION AND/OR SELECTIVE BACKLIGHT CONTROL TO REDUCE MOIRE INTERFERENCE IN A DISPLAY SYSTEM INCLUDING MULTIPLE DISPLAYS

(71) Applicant: PURE DEPTH LIMITED, Panmure (NZ)

(72) Inventors: Gareth P. BELL, Auckland (NZ); Darryl SINGH, Auckland (NZ); John D. NEWTON, Auckland (NZ)

(21) Appl. No.: 15/338,777

(22) Filed: Oct. 31, 2016

Related U.S. Application Data
(60) Provisional application No. 62/248,973, filed on Oct. 30, 2015.

(51) Int. Cl. G09G 3/00; H01L 27/32; G09G 3/36; G02F 1/1335; G09G 3/3208

(52) U.S. Cl. CPC G09G 3/007; G02F 1/133621; G09G 3/003; G09G 3/3208; G09G 3/3607; H01L 27/3225; H01L 27/3211; H01L 27/322; G02B 6/0068

(57) ABSTRACT

A multi-display system (e.g., a display including multiple display panels) includes at least first and second displays (e.g., display panels or display layers) arranged substantially parallel to each other in order to display three-dimensional (3D) features to a viewer(s). Panel vibration (e.g., lateral vibration) and/or selective backlight control is/are used to reduce moire interference in order to improve image quality to viewer(s).

This application is related to and claims priority on prior provisional U.S. Patent Application No. 62/248,973, filed Oct. 30, 2015 (Our Ref. 6468-4), which is hereby incorporated herein by reference in its entirety.

### FIELD OF THE INVENTION

This invention relates to a multi-display system (e.g., a display including multiple display panels), where at least first and second displays (e.g., display panels or display layers) are arranged substantially parallel to each other in order to display three-dimensional (3D) features to a viewer(s). Thus, this invention relates generally to displays and, more particularly, to display systems and methods for displaying three-dimensional features. Panel vibration (e.g., lateral vibration) and/or selective backlight control is/are used to reduce moire interference in order to improve image quality to viewer(s).

### BACKGROUND AND SUMMARY OF THE INVENTION

Traditionally, displays present information in two dimensions. Images displayed by such displays are planar images that lack depth information. Because people observe the world in three-dimensions, there have been efforts to provide displays that can display objects in three-dimensions. For example, stereo displays convey depth information by displaying offset images that are displayed separately to the left and right eye. When an observer views these planar images they are combined in the brain to give a perception of depth. However, such systems are complex and require increased resolution and processor computation power to provide a realistic perception of the displayed objects.

Multi-component displays including multiple display screens in a stacked arrangement have been developed to display real depth. Each display screen may display its own image to provide visual depth due to the physical displacement of the display screens. For example, multi-display systems are disclosed in U.S. Patent Publication Nos. 2015/0323805 and 2016/0012630, the disclosures of which are both hereby incorporated herein by reference.

When a first and second displays or display layers are conventionally stacked on each other in a multi-display system, undesirable moire interference occurs. The moire interference is caused by interactions between the color filters within the layers when projected onto the viewer's retina. For example, when green color filters overlap, light is transmitted making for a comparative bright patch. When a green filter is over say a red filter, not as much light will be transmitted making for a dark region. Since the rear and front displays or display layers have slightly different sizes when projected onto the retina, the pixels will slowly change from being in phase to out of phase. This has the effect of producing dark and bright bands otherwise known as moire interference.

There have been several approaches to removing moire interference in a multi-layer display (MLD) system. Some approaches rely on removing unwanted frequency components by spatial filtering. This can be accomplished with either a diffuser type system whereby an element with a refractive index of about 1.5 has random surface perturbations, or a diffraction type system. The performance of these systems in terms of visual aesthetics (e.g., how blurry the image looks; how much residual moire is left; the effect on polarization; and cost, etc.) depend greatly on the system configuration. Certain MLD systems solely utilize diffusive optics to blur the rear-most display layer. This approach suffers from the following limitations: (a) the diffusing element utilizes a specialized diffuser pattern, which is difficult to obtain; (b) the diffusing element sits between polarizers and both the film substrate and stiffener substrate must be free of any birefringence; and (c) the diffusing element requires a separate stiffener component (usually glass) which adds weight and expense to the final display system. As a result, MLD systems using solely a diffuser to address moire issues do not provide an ideal solution to reducing moire interference, especially as those systems have reduced form factors.

Historic and present methodologies that rely only on diffusers to address moire interference do not provide an acceptable solution to the moiré issue without the introduction of significant and detrimental side-effects to image quality.

Certain example embodiments of the instant invention provide solution(s) that make moiré interference in MLD systems vanish or substantially vanish. In certain example embodiments of this invention, the MLD system includes first and second displays. Panel vibration (e.g., lateral vibration) and/or selective backlight control is/are used to reduce moire interference in order to improve image quality to viewer(s). In an example embodiment of this invention, only one of the two display panels in the MLD system is vibrated in order to blur out, or substantially blur, color filters instead of having to rely solely on a diffuser or the like. Such moire interference reduction techniques (panel vibration and/or backlight control) may or may not be used in combination with other moire reducing techniques such as diffuser(s) and/or refractive element(s) according to various embodiments of this invention.

In certain example embodiments of this invention, there is provided a display device comprising: a first display panel in a first plane for displaying a first image; a second display panel in a second plane for displaying a second image, wherein said first and second planes are approximately parallel to each other; and a vibrator for vibrating one of the first and second display panels, but not the other of the first and second display panels, in order to reduce moiré interference.

In certain example embodiments of this invention, there is provided a method for displaying images via a display apparatus, the method comprising: providing a first display in a first plane displaying a first image; providing a second display in a second plane displaying a second image, wherein said first and second planes are approximately parallel to each other; and vibrating the first display in order to reduce moiré interference.

In certain example embodiments of this invention, there is provided a method for displaying images via a display apparatus, the method comprising: providing a first display in a first plane displaying a first image; providing a second display in a second plane displaying a second image, wherein said first and second planes are approximately parallel to each other; and selectively controlling differently colored light sources of a backlight of the display apparatus based at least on a position of at least one of the displays.

### BRIEF DESCRIPTION OF THE DRAWINGS

These and other features and advantages may be better and more completely understood by reference to the following detailed description of exemplary illustrative embodiments in conjunction with the drawings, of which:

FIG. 1 is a side cross sectional view of a MLD system including first and second displays stacked on each other according to an example embodiment of this invention;

FIG. 2 is a schematic side cross sectional view illustrating a MLD system including first and second displays stacked on each other according to an example embodiment of this invention;

FIG. 3 is a top view illustrating on the left a panel with no vibration, and on the right a panel being vibrated, in order to reduce moire interference in the MLD system of any embodiment herein; and

FIG. 4 is a timing diagram illustrating selective backlight control in order to reduce moire interference according to an example embodiment of this invention that may be used in combination with any and/or all of FIGS. 1-3.

### DETAILED DESCRIPTION

This invention relates to a multi-display system (e.g., a display including multiple display panels), where at least first and second displays (e.g., display panels or display layers) are arranged substantially parallel to each other in order to display three-dimensional (3D) features to a viewer(s). The displays may be flat or curved in different embodiments. Thus, embodiments of this invention relate generally to displays and, more particularly, to display systems and methods for displaying three-dimensional features. MLDs according to example embodiments of this invention may be used, for example, as displays in vehicle dashes in order to provide 3D images (e.g., for speedometers, vehicle gauges, vehicle navigation displays, etc.).

The color moiré interference problem is caused for example by pattern regularity of both LCD color filter arrays as the RGB pixels are aligned into RGB columns. Color moiré interference is largely prevalent in the horizontal direction.

Certain example embodiments of the instant invention provide solution(s) that make moiré interference in MLD systems vanish or substantially vanish. In certain example embodiments of this invention, the MLD system includes at least first and second displays that are provided in a stacked relationship so as to be located on different respective planes that are parallel or substantially parallel to each other. In certain example embodiments of this invention, the MLD system includes first and second displays. Panel vibration (e.g., lateral vibration such as introduction of Perlin noise) and/or selective backlight control is/are used to reduce moire interference in order to improve image quality to viewer(s). In an example embodiment of this invention, only one of the two display panels in the MLD system is vibrated in order to blur out, or substantially blur, color filters instead of having to rely solely on a diffuser or the like. The other panel is not vibrated. Such moire interference reduction techniques (panel vibration and/or backlight control) may or may not be used in combination with other moire reducing techniques such as diffuser(s) and/or refractive element(s) according to various embodiments of this invention.

It is noted that the color filters of the display panels discussed herein are referred to as red (R), green (G) and blue (B) colored filters/pixels. Likewise, R, G and B LEDs are discussed as light sources in backlights herein. However, it is noted that other colors may additionally, or instead, be used. For instance, cyan and/or white filters, pixels, and light sources are also possible in addition to or instead of red, green, and/or blue.

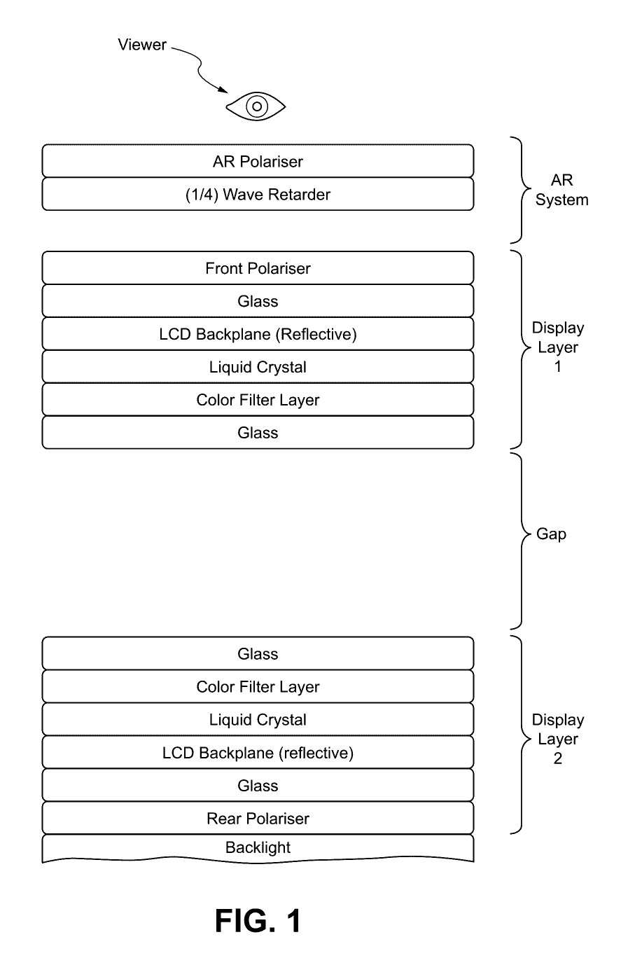

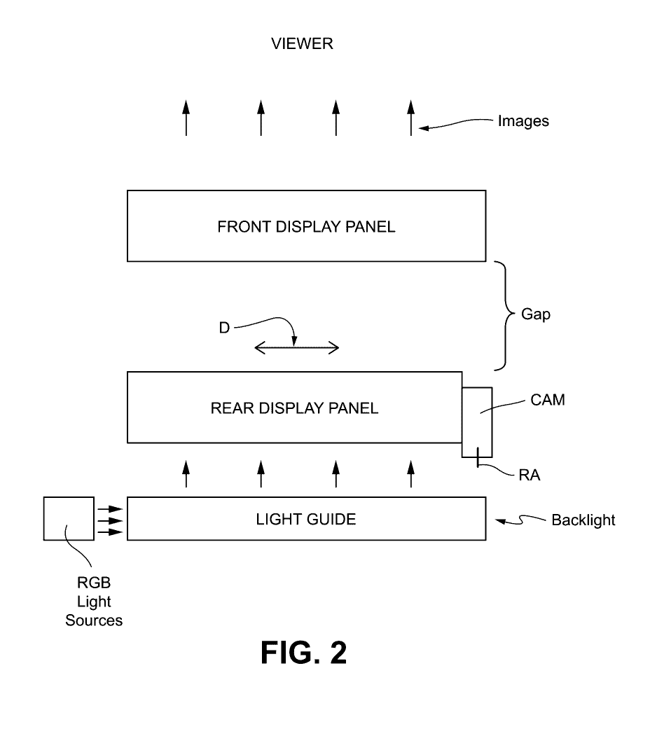

The MLD system shown in FIGS. 1-2 has two overlapping and substantially parallel displays. The displays (or display layers, or display panels) of the MLD herein may be LCDs, OLEDs, or the like. Twisted nematic (TN) LCDs may follow a fairly generic pixel layout, such as a square divided into three portions running horizontally with red green and blue sub-pixels. The sub-pixels may be separated by a black mask in the horizontal and vertical directions. There is often a square protrusion in the corner of the sub-pixel to cover the drive transistor. There are several different types of pixel technology that enable wide screen viewing and temporal performance required for modern desktop monitors and televisions. Embodiments of the present invention are compatible with all of these LCDs, since the backplanes are designed to follow the basic RGB stripe pixel layout. As such, the backplane layout required for each pixel not need to change, only the color filter mask layout. For example, pixel types by manufacturer are: Panasonic (IPS Pro), LG Display (H-IPS & P-IPS), Hannstart (S-IPS), AU Optronics (A-MVA), Samsung (AFFS), S-LCD (S-PVA), and Sharp Corporation (ASV and MVA). IPS type LCDs, or other LCD types, may also be used. In certain embodiments, both displays or display layers may be OLEDs, or one display may be an OLED and the other an LCD. Note that in OLEDs, respective sub-pixels or pixels would be filled with red, green, and blue material.

FIG. 1 illustrates a MLD according to an example embodiment of this invention. Display or display layer 2 is closest to the backlight of the MLD, and it may be desirable to have its backplane facing the backlight system to recycle light that may pass through row drivers, column drivers, transistors, and storage capacitance lines into the backlight. A two polarizer configuration may be used, as shown in the figure, and gaps may be designed to include air or material having birefringence designed to maintain black state of the display when desired. The gap may include material having a refractive index matched closely to glass or the layers on either side to reduce internal reflection and/or depolarization effects. For the front display or display layer 1, its backplane may be oriented opposite to that of display or display layer 2. In particular, for the front display 1 its backplane may be oriented to face the viewer to reduce internal reflections. Thus, it can be seen in FIG. 1 that the color filter layers (each of which may be made up of one or more layers) of the respective displays 1 and 2 face each other, with no liquid crystal layer from either display being located between the color filter layers of the first and second displays. In certain example embodiments, to reduce external reflections of ambient light, there may be provided an antireflective system such as that shown in FIG. 1 made up of quarter wave retarder and an antireflective polarizer, so that ambient light that would normally be reflected would undergo a quarter wave rotation on the first pass through the AR polarizer, is reflected by the backplane elements, undergoes a second rotation through the quarter wavelength retarder. By the time it goes through this second rotation, it is substantially orthogonal to the transmission axis of the AR polarizer and thus will be substantially absorbed. Additionally, black mask (BM) or other non-reflective material may be added behind the conductive traces of the displays to reduce reflections. Additionally, antireflective (AR) coating(s) may be applied to the interior surfaces in certain example embodiments of this invention. As explained herein, the use of the vibration and/or selective backlight control to reduce moire interference may avoid the need for a diffuser to be provided in the gap between the two display panels of the MLD system.

FIG. 2 is a schematic diagram, representative of the FIG. 1 MLD system or any other suitable or applicable MLD system having first and second overlapping display panels. As shown in FIG. 2, the MLD system includes first and second display panels that are arranged substantially parallel to each other with a gap (e.g., air gap, or gap filled with index matching material) therebetween. Each display panel may be an LCD, OLED, or the like as discussed above. A backlight provided behind the rear panel includes a plurality of light sources (e.g., red, green, and blue LED light sources) which direct colored light into a light guide which redirects the light toward the two display panels as shown in FIG. 2. The backlight shown in FIG. 2 is an edge-mounted backlight, because the color LED light sources are provided along an edge(s) of the lightguide. Alternatively, an area array type of backlight could instead be used with colored and/or white light sources.

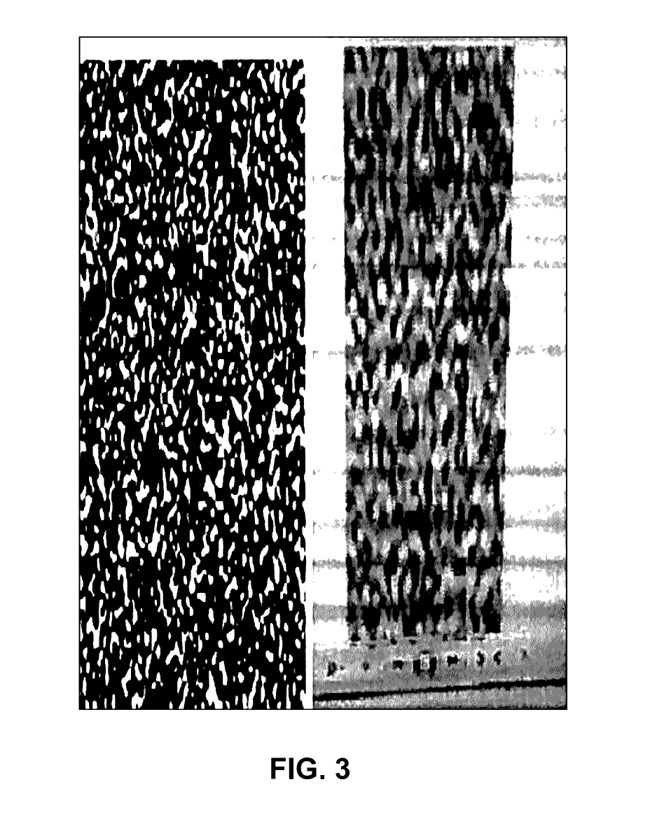

A movable (e.g., rotatable) cam, when moved (e.g., rotated), introduces panel vibration (e.g., Perlin noise) to the rear display panel thereby moving the rear display panel back and forth in direction D as shown in FIG. 2. The eccentric cam, for example, may be rotated about rotational axis/shaft RA in order to cause the rear panel to move back and forth in direction D. The cam may directly or indirectly abut the rear panel in various embodiments of this invention in order to impart such vibration to the rear panel. A biasing forced, such as via a spring (not shown), may be provided on the side of the panel opposite the cam in certain example embodiments effectively giving the cam a force against which to move the panel. Thus, it will be appreciated that the cam causes only one of the two display panels in the MLD system to vibrate (the other display panel is not vibrated). While an eccentric rotating cam, driven by a motor via rotating shaft RA, is shown as a vibrating device for vibrating one of the panels in FIG. 3, other types of vibrating devices (e.g., reciprocating cam, reciprocating ram, spring biasing member, etc.) may instead or in addition be used. FIG. 3 is a top view illustrating on the left a panel with no vibration, and on the right a panel being vibrated, in order to reduce moire interference in the MLD system of any embodiment herein. While FIG. 2 shows the rear display panel being vibrated, instead the front display panel may be vibrated in alternative embodiments of this invention.

Perlin noise is an example type of vibration that may be applied to one of the two display panels to reduce moire interference. Perlin noise is a type of gradient noise, and has a pseudo-random appearance. In certain embodiments, all visual details of Perlin noise may be the same size. In certain example instances, multiple scaled copies of Perlin noise can be used. While Perlin noise is an example type of vibration that may be used in certain embodiments herein, this invention is not so limited as other types of vibration may also be used.

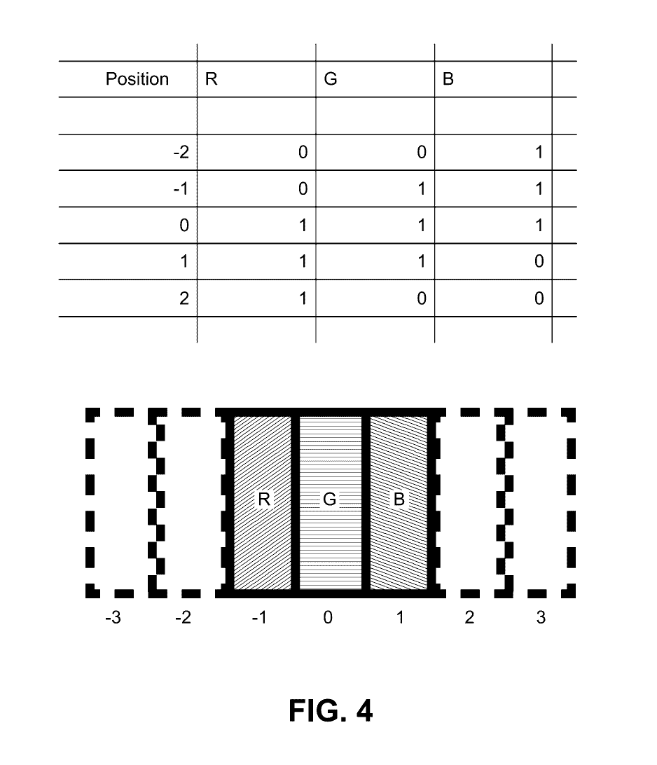

Referring to FIG. 4, selective backlight control may be used in conjunction with panel vibration in order to reduce moire interference in order to improve image quality to viewer(s). FIG. 4 is a timing diagram, that when used allows one to be able to maintain a white pixel on a black background without any additional blurring. Red (R), green (G), and blue (B) subpixels, making up a pixel, are shown in FIG. 4. The color filters of the respective R, G and B subpixels are shown as parallel stripes in FIG. 4, although other shapes are possible for the color filters and/or subpixels. The subpixels in FIG. 4 may be, for example, in the panel that is subject to the vibration discussed herein. In the three right-most columns in the upper portion of FIG. 4, a “0” is used to indicate that a particular color LED source in the backlight is turned off, and a “1” is used to indicated that a particular color LED source in the backlight is turned on. Thus, for example, at timing position −1, the red LED source(s) in the backlight are off while the green and blue LED sources in the backlight are on. As another example, at timing position −2, the red and green LED sources in the backlight are off while the blue LED source(s) in the backlight is on.

The green (G) pixel or subpixel is used, for example, in FIG. 4 to track the position of the panel. At timing position 0 (see green pixel in the center), the R, G and B LED sources in the backlight are all on. Then, when the green pixel or subpixel has moved either one or two sub-pixels to the right due to the vibration (see timing positions 1 and 2), the red LED source(s) in the backlight is on and the red will appear to cover the entire pixel. However, since the red LED source(s) in the backlight is turned off when the green pixel or sub-pixel moves one or two pixels to the left due to the vibration (see timing positions −1 and −2), the red sub-pixel will not appear to move beyond the LH boundary of the pixel. This prevents (or reduces) the viewer seeing a blurred pixel. However, from a moire standpoint, as shown in FIG. 4, when one can move the red sub-pixel stripe (e.g., red color filter pixel or subpixel) across the green and blue positions, and flash the red portion of the back-light on when in those positions, this will make the panel appear a uniform white when “fused” by the viewer's visual system. The same applies with blue, except in the opposite movement direction.

When the green (G) pixel or subpixel (the same could also be said for the R or B subpixels, because all the subpixels and pixels move together when the panel is vibrated such as with Perlin noise) has moved either one or two sub-pixels to the left due to the vibration (see timing positions −1 and −2), the blue LED source(s) in the backlight is on and the blue will appear to cover the entire pixel. However, since the blue LED source(s) in the backlight is turned off when the green pixel or sub-pixel moves one or two pixels to the right due to the vibration (see timing positions 1 and 2), the blue sub-pixel will not appear to move beyond the RH (righthand) boundary of the pixel. This prevents (or reduces) the viewer seeing a blurred pixel. Thus, from a moire standpoint, as shown in FIG. 4, when one can move the blue sub-pixel stripe (e.g., blue color filter pixel or subpixel) across the green and blue positions, and flash the blue portion of the back-light on when in those positions, this will make the panel appear a uniform white when “fused” by the viewer's visual system.

According, it can be seen that panel vibration and/or selective backlight control may be used to reduce moire interference in a MLD system in embodiments of this invention.

In an example embodiment of this invention, there is provided a display device comprising: a first display panel in a first plane for displaying a first image; a second display panel in a second plane for displaying a second image, wherein said first and second planes are approximately parallel to each other; and a vibrator for vibrating one of the first and second display panels, but not the other of the first and second display panels, in order to reduce moiré interference.

In the display device of the immediately preceding paragraph, the vibrator may comprise an eccentric cam configured to be driven by a motor.

In the display device of any of the preceding two paragraphs, the vibrator may be for vibrating said one of the first and second display panels at least in a direction within the plane in which said one panel is located.

In the display device of any of the preceding three paragraphs, the other of the first and second display panels is not configured to be vibrated.

The display device of any of the preceding four paragraphs may further comprise a backlight including first, second, and third differently colored light sources, and wherein said first, second, and third differently colored light sources are each selectively controlled based on a position of said one of the first and second display panels.

In the display device of any of the preceding five paragraphs, there may be a red colored source in the backlight configured to be turned on when a red colored subpixel is in a given position and when the red colored subpixel is shifted one and/or two subpixels to one side of the given position, but configured to be turned off when the red colored subpixel is shifted to the other side of the given position.

In the display device of any of the preceding six paragraphs, there may be a blue colored source in the backlight configured to be turned on when a blue colored subpixel is in a given position and when the blue colored subpixel is shifted one and/or two subpixels to one side of the given position, but configured to be turned off when the blue colored subpixel is shifted to the other side of the given position. Red, green and blue colored sources in the backlight may all be configured to be turned on when the blue colored subpixel is in the given position.

In the display device of any of the preceding seven paragraphs, the first and second display panels may comprise liquid crystal displays and/or OLEDs.

In the display device of any of the preceding eight paragraphs, said one of the first and second display panels may be a rear display or a front display.

In the display device of any of the preceding nine paragraphs, the vibrator may be configured to vibrate said one of the first and second display panels in a manner so as to introduce Perlin noise to said one display panel.

While the foregoing disclosure sets forth various embodiments using specific block diagrams, flowcharts, and examples, each block diagram component, flowchart step, operation, and/or component described and/or illustrated herein may be implemented, individually and/or collectively, using a wide range of hardware, software, or firmware (or any combination thereof) configurations. In addition, any disclosure of components contained within other components should be considered as examples because many other architectures can be implemented to achieve the same functionality.

The process parameters and sequence of steps described and/or illustrated herein are given by way of example only and can be varied as desired. For example, while the steps illustrated and/or described herein may be shown or discussed in a particular order, these steps do not necessarily need to be performed in the order illustrated or discussed. The various example methods described and/or illustrated herein may also omit one or more of the steps described or illustrated herein or include additional steps in addition to those disclosed.

While various embodiments have been described and/or illustrated herein in the context of fully functional computing systems, one or more of these example embodiments may be distributed as a program product in a variety of forms, regardless of the particular type of computer-readable media used to actually carry out the distribution. The embodiments disclosed herein may also be implemented using software modules that perform certain tasks. These software modules may include script, batch, or other executable files that may be stored on a computer-readable storage medium or in a computing system. These software modules may configure a computing system to perform one or more of the example embodiments disclosed herein. Various functions described herein may be provided through a remote desktop environment or any other cloud-based computing environment.

The foregoing description, for purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to best explain the principles of the invention and its practical applications, to thereby enable others skilled in the art to best utilize the invention and various embodiments with various modifications as may be suited to the particular use contemplated.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

Embodiments according to the present disclosure are thus described. While the present disclosure has been described in particular embodiments, it should be appreciated that the disclosure should not be construed as limited by such embodiments.

1. A display device comprising:
a first display panel in a first plane for displaying a first image;
a second display panel in a second plane for displaying a second image, wherein said first and second planes are approximately parallel to each other; and
a vibrator for vibrating one of the first and second display panels, but not the other of the first and second display panels, in order to reduce moiré interference.

2. The display device of claim 1, wherein the vibrator comprises an eccentric cam configured to be driven by a motor.

3. The display device of claim 1, wherein the vibrator is for vibrating said one of the first and second display panels at least in a direction within the plane in which said one panel is located.

4. The display device of claim 1, wherein the other of the first and second display panels is not configured to be vibrated.

5. The display device of claim 1, further comprising a backlight including first, second, and third differently colored light sources, and
wherein said first, second, and third differently colored light sources are each configured to be selectively controlled based on a position of said one of the first and second display panels.

6. The display device of claim 5, wherein a red colored source in the backlight is configured to be turned on when a red colored subpixel is in a given position and when the red colored subpixel is shifted one and/or two subpixels to one side of the given position, but is configured to be turned off when the red colored subpixel is shifted to the other side of the given position.

7. The display device of claim 5, wherein a blue colored source in the backlight is configured to be turned on when a blue colored subpixel is in a given position and when the blue colored subpixel is shifted one and/or two subpixels to one side of the given position, but is configured to be turned off when the blue colored subpixel is shifted to the other side of the given position.

8. The display device of claim 1, red, green and blue colored sources in the backlight are all configured to be turned on when the blue colored subpixel is in the given position.

9. The display device of claim 1, wherein the first and second display panels comprise liquid crystal displays.

10. The display device of claim 1, wherein the first and second display panels comprise OLEDs.

11. The display device of claim 1, wherein said one of the first and second display panels is a rear display.

12. The display device of claim 1, wherein said one of the first and second display panels is a front display.

13. The display device of claim 1, wherein the vibrator is configured to vibrate said one of the first and second display panels in a manner so as to introduce Perlin noise to said one display panel.

14. A method for displaying images via a display apparatus, the method comprising:
providing a first display in a first plane displaying a first image;
providing a second display in a second plane displaying a second image, wherein said first and second planes are approximately parallel to each other; and
vibrating the first display in order to reduce moiré interference.

15. The method of claim 14, further comprising selectively controlling first, second, and third differently colored light sources of a backlight of the display apparatus based at least on a position of said first display.

16. The display device of claim 15, further comprising turning on a red colored source in the backlight when a red colored subpixel in the first display is in a given position and when the red colored subpixel is shifted one and/or two subpixels to one side of the given position, and turning off the red colored source when the red colored subpixel is shifted to the other side of the given position.

17. The display device of claim 15, further comprising turning on a blue colored source in the backlight when a blue colored subpixel in the first display is in a given position and when the blue colored subpixel is shifted one and/or two subpixels to one side of the given position, and turning off the blue colored source when the blue colored subpixel is shifted to the other side of the given position.

18. The method of claim 14, wherein the second display is not vibrated when the first display is being vibrated.

19. A method for displaying images via a display apparatus, the method comprising:
providing a first display in a first plane displaying a first image;
providing a second display in a second plane displaying a second image, wherein said first and second planes are approximately parallel to each other; and
selectively controlling differently colored light sources of a backlight of the display apparatus based at least on a position of at least one of the displays.

20. The display device of claim 19, further comprising turning on a red colored source in the backlight when a red colored subpixel in the first display is in a given position and when the red colored subpixel is shifted one and/or two subpixels to one side of the given position, and turning off the red colored source when the red colored subpixel is shifted to the other side of the given position.

21. The display device of claim 19, further comprising turning on a blue colored source in the backlight when a blue colored subpixel in the first display is in a given position and when the blue colored subpixel is shifted one and/or two subpixels to one side of the given position, and turning off the blue colored source when the blue colored subpixel is shifted to the other side of the given position.
